(19) United States
(12) Patent Application Publication
(10) Pub. No.: US 2014/0252393 A1
(43) Pub. Date: Sep. 11, 2014

(54) LIGHT-EMITTING STRUCTURE

(71) Applicant: LUXO-LED TAIWAN LIMITED, Taipei City (TW)

(72) Inventor: Percy VANLUCHENE, Taipei City (TW)

(73) Assignee: LUXO-LED TAIWAN LIMITED, Taipei City (TW)

(21) Appl. No.: 14/205,084

(22) Filed: Mar. 11, 2014

Related U.S. Application Data
(60) Provisional application No. 61/776,640, filed on Mar. 11, 2013.

(51) Int. Cl. H01L 33/50

(52) U.S. Cl. CPC H01L 33/505
USPC 257/98

(57) ABSTRACT

A light-emitting structure is provided. The disclosed light-emitting structure may include a light-emitting diode (LED) die, a plurality of light-penetrating microspheres covered a light emitting surface of the LED die, and a light-penetrating structure, disposed over the LED die and the light-penetrating microspheres, for converting light emitting from the LED die. Another light-emitting structure is also provided. The disclosed light-emitting structure may include a light-emitting diode (LED) die, a plurality of light-penetrating microspheres covered a light emitting surface of the LED die, and a light-penetrating structure, disposed between the LED die and the light-penetrating microspheres, for converting light emitting from the LED die.

### CROSS REFERENCE TO RELATED APPLICATION

The application claims priority based on U.S. provisional application, Ser. No. 61/776,640, filed 2013 Mar. 11, entitled LIGHT-EMITTING STRUCTURE, which is hereby incorporated by reference in its entirely.

### BACKGROUND

### Technical Field

The present disclosure relates to a light-emitting structure, and more particularly, to a light-emitting structure capable of enabling the light emitted from the light-emitting structure to substantially travel in a predetermined direction.

### SUMMARY

A light-emitting structure is provided. The disclosed light-emitting structure may include a light-emitting diode (LED) die, a plurality of light-penetrating microspheres covered a light emitting surface of the LED die, and a light-penetrating structure, disposed over the LED die and the light-penetrating microspheres, for converting light emitting from the LED die. Another light-emitting structure is also provided. The disclosed light-emitting structure may include a light-emitting diode (LED) die, a plurality of light-penetrating microspheres covered a light emitting surface of the LED die, and a light-penetrating structure, disposed between the LED die and the light-penetrating microspheres, for converting light emitting from the LED die.

### BRIEF DESCRIPTION OF THE DRAWINGS

The present disclosure will become more fully understood from the detailed description given herein below for illustration only, and thus are not limitative of the present disclosure, and wherein:

FIG. 1 is a schematic diagram of a light-emitting structure according to one embodiment of the present disclosure;

FIG. 2 is a schematic diagram of another light-emitting structure according to one embodiment of the present disclosure;

FIG. 3 is a schematic diagram of another light-emitting structure according to one embodiment of the present disclosure;

FIG. 4A illustrates another light-emitting structure according to one embodiment of the present disclosure;

FIG. 4B illustrates the other light-emitting structure according to one embodiment of the present disclosure; and

FIG. 5 shows an example light guiding lens assembly used by the light-emitting structure according to one embodiment of the present disclosure.

### DETAILED DESCRIPTION

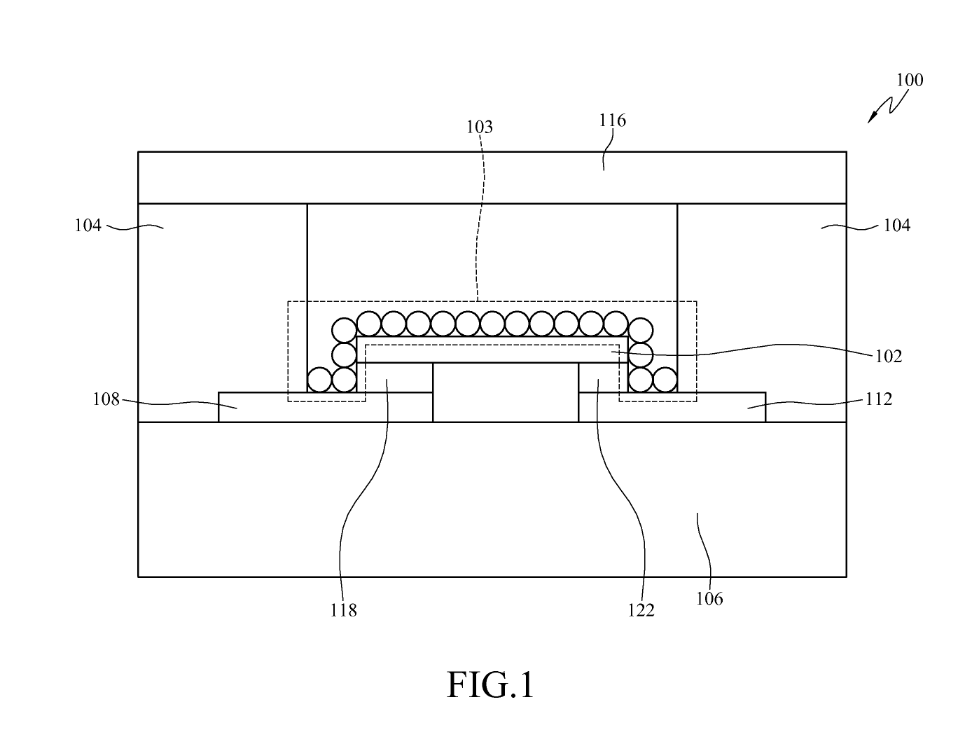

Please refer to FIG. 1 of a schematic diagram of a light-emitting structure 100 according to one embodiment of the present disclosure. The light-emitting structure 100 may include a light-emitting diode (LED) die 102, a plurality of light-penetrating microspheres 103, a lateral light blocking wall 104 enclosing the LED die 102 and the light-penetrating microspheres 103, a substrate 106, metal contacts 108 and 112, and a light-penetrating structure 116 over the LED die 102 and the light-penetrating microspheres 103 and in contact with the lateral light blocking wall 104. In addition, a heat dissipation layer may also be disposed beneath the substrate 106. The light-penetrating structure 116 may have a various 3D shape, and/or microstructured surface and also can have various optical and photonic characteristics (e.g. CFQ, color changing properties, CRI enhancing properties) The light blocking wall 104 might be omitted and the light-penetrating structure 116 may immediately connected to the substrate 106. The light-emitting structure 100 may further include bonding pads 118 and 122 electrically contacting the metal contacts 108 and 112, respectively.

The light-penetrating microspheres 103 may be adapted to position in a predetermined fashion in order to cover or surround the entire LED die 102. In one implementation, the light-penetrating microspheres 103 may be in the form of the plastic powder and may cover or surround the LED die 102 by coating. In another implementation, the light-penetrating microspheres 103 may cover or surround the LED die 102 through a bonding agent such as glue. In another implementation, the light-penetrating microspheres 103 may be in the form of glass balls. The microspheres can be mixed at randomly in an agent (e.g. silicone) to create a floating effect of the microsphere.

The lateral light blocking wall 104 may be used to eliminate the possibility of the light emitted from the LED die 102 of laterally travelling out of the light-emitting structure. The lateral light blocking wall 104 may be formed out of material of copper (Cu) or epoxy, or silicone, or any other material which is stable enough to form a solid structure. In the case of the copper forming the lateral light blocking wall 104, an isolation layer might be applied onto the base of the lateral light blocking wall 104 to prevent the base from being electrically connected to the top of the same lateral light blocking wall 104. Further, a reflective layer formed in silver (Ag) may be placed on the top of the lateral light blocking wall 104 for enhancing the reflection. With the lateral light blocking wall 104, the light emitted from the LED die 102 may be guided upwardly. In one implementation, the light-penetrating structure 116 may be implemented in form of a color converting crystal, or a lamination of several layers (one of them can be a color converting crystal) with different properties to enhance the desired output, which may not just allow for the light from the LED die 102 to penetrate but also convert the color of such light. In other words, the light-penetrating structure 116 may serve several purposes, such as adjusting correlated color temperature (CCT), color rendering index (CRI), optical diffusing, and/or optical focusing. The substrate 106, which is now a physical part, might become the integral part of a housing onto which the die will be bonded in the future.

The bonding pads 118 and 122, which are electrically coupled to the metal contacts 108 and 112, may be used as negative and positive electrodes for the LED die 102. And the heat arising out of the operation of the LED die 102 may be transmitted out of the light-emitting structure 100 through the metal contacts 108 and 112, the substrate 106, and the heat dissipation layer. It is worth noting that in one implementation the substrate 106 may be a ceramic substrate and 125-500 micrometers in thickness. To be noted, the thickness is not a limiting factor.

The LED die 102 may be flipped in order to be in contact with the metal contacts 108 and 112 through the bonding pads 118 and 122 using the flip-chip technology.

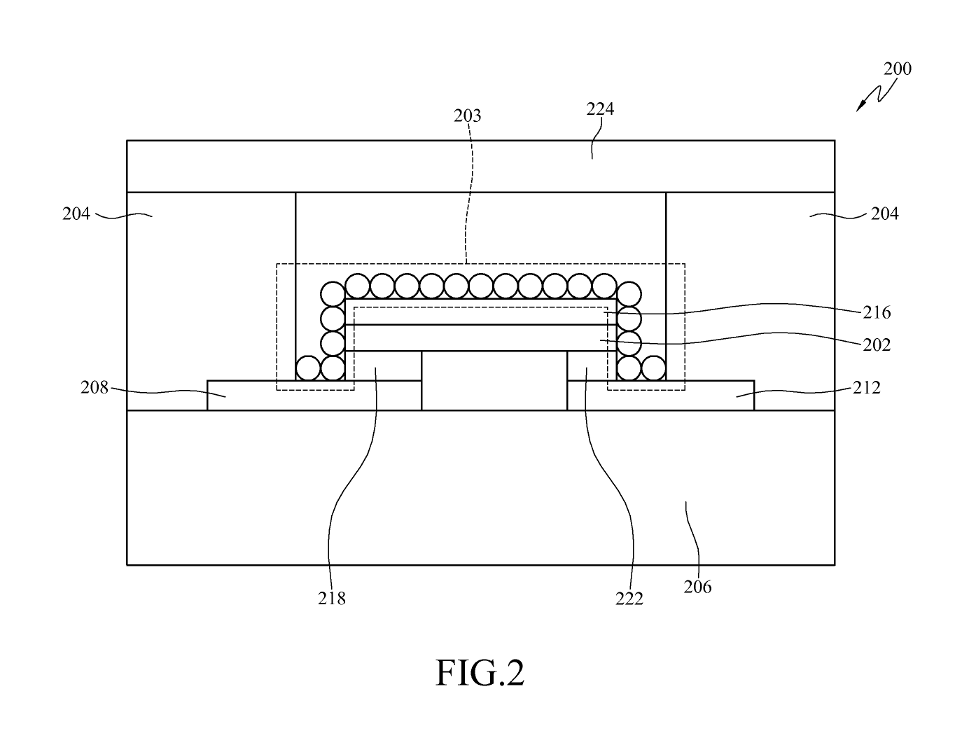

Please refer to FIG. 2 illustrating another light-emitting structure 200 according to one embodiment of the present disclosure. The light-emitting structure 200 may include a light-emitting diode (LED) die 202, a plurality of light-penetrating microspheres 203, a lateral light blocking wall 204 enclosing the LED die 202 and the light-penetrating microspheres 203, a substrate 206, metal contacts 208 and 212, and a light-penetrating structure 216. In addition, a heat dissipation layer may also be disposed beneath the substrate 206. The light-emitting structure 200 may further include bonding pads 218 and 222 electrically contacting the metal contacts 208 and 212, respectively. The light-emitting structure 200 also includes a protective film 224 (could also be considered as another light-penetrating structure mentioned before) contacting the lateral light blocking wall 204. The protective film 224 may have a various 3D shape, and/or microstructured surface and also can have various optical and photonic characteristics (e.g. CFQ, color changing properties, CRI enhancing properties) The light blocking wall 204 might be omitted and the protective film 224 may immediately connected to the substrate 206.

Instead of being placed above both the LED die 202 and the light-penetrating microspheres 203 as illustrated in FIG. 1, the light-penetrating structure 216 (or a lamination of different layers with optical and photonic characteristics) may be placed between the LED die 202 and the light-penetrating microspheres 203. Under this arrangement, the intended functions of the light-penetrating structure 216, which may include allowing for the light emitted from the LED die 202 to penetrate and converting the color of the same light emitted from the LED die 202, may not be compromised.

The light-penetrating microspheres 203 may be adapted to position in a predetermined fashion in order to cover or surround both the entire LED die 202 and the light-penetrating structure 216. Similar to the way the light-penetrating microspheres 103 covers or surrounds the LED die 102, the light-penetrating microspheres 203 may be in the form of the plastic powder covering or surrounding the light-penetrating structure 216 and the LED die 202 by coating. Alternatively, the light-penetrating microspheres 203 may cover or surround the LED die 102 and the light-penetrating structure 216 through gluing.

The lateral light blocking wall 204 meanwhile may be used to prevent the light emitted from the LED die 202 from laterally travelling out of the light-emitting structure 200, which may ensure the light emitted from the LED die 202 may be guided upwardly.

The bonding pads 218 and 222, which are electrically coupled to the metal contacts 208 and 212, may be used as negative and positive electrodes for the LED die 202. And the heat arising out of the operation of the LED die 202 may be transmitted out of the light-emitting structure 200 through the metal contacts 208 and 212, the substrate 206, and the heat dissipation layer. Additionally, the LED die 202 may be flipped in order to be in contact with the metal contacts 208 and 212 through the bonding pads 218 and 222 using the flip-chip technology. Plus, it is worth noting that the protective film 224 may be used to prevent foreign particles (for example, dust) and the moisture from invading into the light-emitting structure 200. Also, the protective film 224 may serve as a color converting layer. The protective film 224 layer can have various shapes and surface structures with different optical and photonic properties.

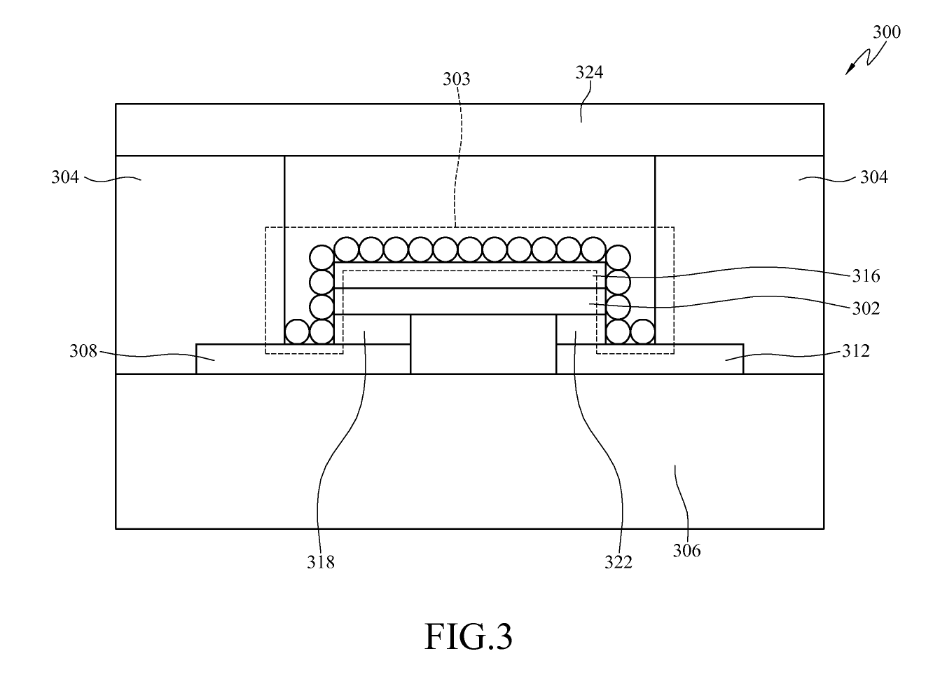

Please refer to FIG. 3 illustrating another light-transmitting structure 300 according to one embodiment of the present disclosure. The light-emitting structure 300 may include a light-emitting diode (LED) die 302, a plurality of light-penetrating microspheres 303, a lateral light blocking wall 304 enclosing the LED die 302 and the light-penetrating microspheres 303, a substrate 306, metal contacts 308 and 312, and a light-penetrating structure 316 placed between the light-penetrating microspheres 303 and the LED die 302. In addition, a heat dissipation layer may also be disposed beneath the substrate 306. The light-emitting structure 300 may further include bonding pads 318 and 322 electrically contacting the metal contacts 308 and 312, respectively.

The light-emitting structure 300 may also include a light guiding lens assembly 324 placed above the LED die 302, the light-penetrating microspheres 303, and the light-penetrating structure 316. In one implementation, the light guiding lens assembly 324 may be an array of silicon-based micro prisms. In another implementation, the light guiding lens assembly 324 may be in the form of Fresnel lens. In another implementation, the light guiding lens assembly 324 may be having silicon-based domes.

The light-penetrating microspheres 303 may be adapted to position in a predetermined fashion, in order to cover or surround both the entire LED die 302 and the light-penetrating structure 316. Similar to the way the light-penetrating microspheres 103 covers or surrounds the LED die 302, the light-penetrating microspheres 303 may be in the form of the plastic powder covering or surrounding the light-penetrating structure 316 and the LED die 302 by coating. Alternatively, the light-penetrating microspheres 303 may cover or surround the LED die 302 and the light-penetrating structure 316 through gluing.

Similar to its counterparts in FIGS. 1 and 2, the lateral light blocking wall 304 may be used to prevent the light emitted from the LED die 302 from laterally travelling out of the light-emitting structure 300. Such light may be further guided along a predetermined direction present the light guiding lens assembly 324.

The bonding pads 318 and 322, which are electrically coupled to the metal contacts 308 and 312, may be used as negative and positive electrodes for the LED die 302, respectively. And the heat arising out of the operation of the LED die 302 may be transmitted out of the light-emitting structure 300 through the metal contacts 308 and 312, the substrate 306, and the heat dissipation layer. Additionally, the LED die 302 may be flipped in order to be in contact with the metal contacts 308 and 312 through the bonding pads 318 and 322 using the flip-chip technology.

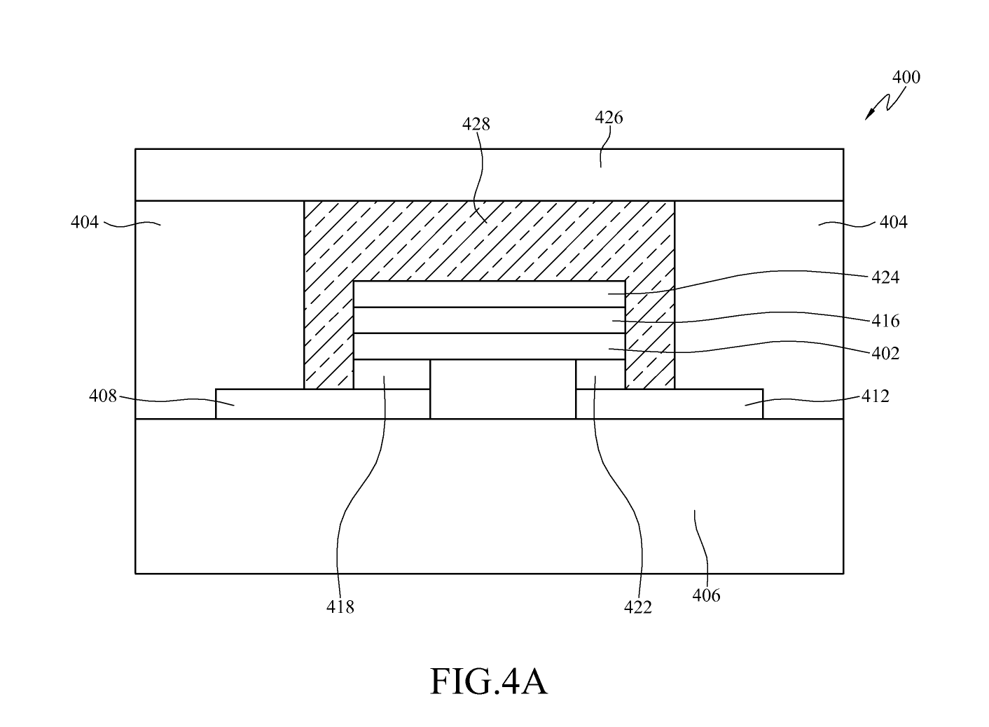

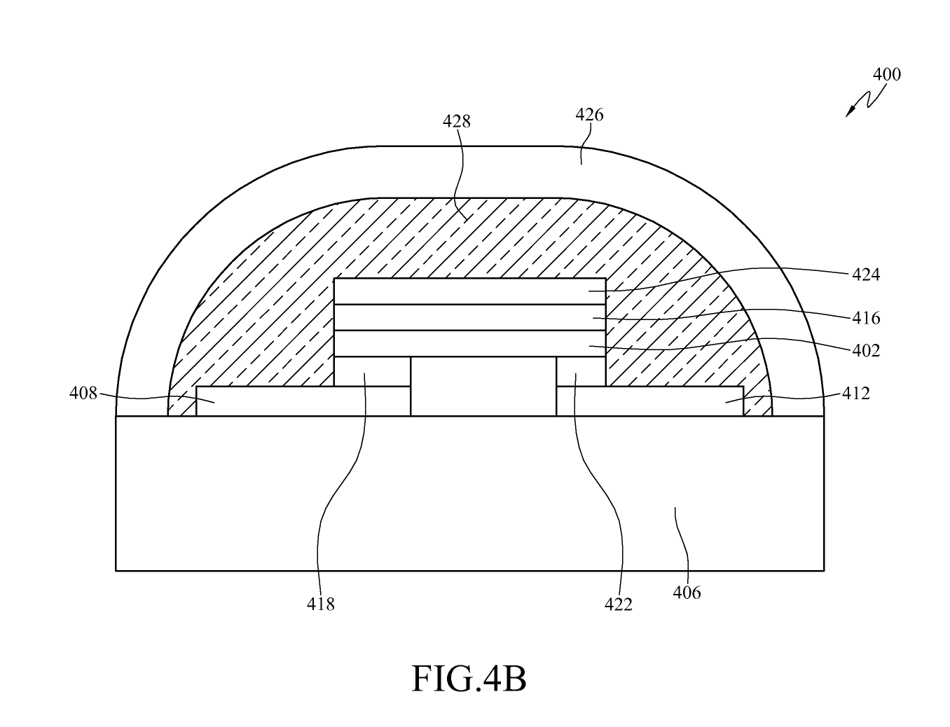

FIG. 4A, meanwhile, illustrates another light-emitting structure 400 according to one embodiment of the present disclosure. The light-emitting structure 400 may include a light-emitting diode (LED) die 402, a lateral light blocking wall 404 enclosing the LED die 402, a substrate 406, metal contacts 408 and 412, and a light-penetrating structure 416 placed above the LED die 402. In addition, a heat dissipation layer may also be disposed beneath the substrate 406. The light-emitting structure 400 may further include bonding pads 418 and 422 electrically contacting the metal contacts 408 and 412, respectively.

Above the light-penetrating structure 416 may be a primary light guiding lens assembly 424. Additionally, the light-emitting structure 400 may further include a secondary light guiding lens assembly 426 contacting the lateral light blocking wall 404. The light-emitting structure 400 may also include a silicon-based filler 428 that may partially or totally fill up the space at least defined by the lateral blocking wall 404, the stacked structure consisting of the LED die 402, the light-penetrating structure 416, and the primary light guiding lens assembly 424, and the secondary light guiding lens assembly 426.

In one implementation, both the primary light guiding lens assembly 424 and the secondary light guiding lens assembly 426 may be an array of silicon-based micro prisms. In another implementation, both the primary light guiding lens assembly 424 and the secondary light guiding lens assembly 426 may be in the form of Fresnel lens. Similar to the light guiding lens assembly 324, both the primary light guiding lens assembly 424 and the secondary light guiding lens assembly 426 may be having the silicon-based domes as well.

The silicon-based filler 428 may replace the light-penetrating microspheres 303 shown in FIG. 3 and may at least serve to allow for the light emitted from the LED die 402 to penetrate. The lateral light blocking wall 404 may be used to prevent the light emitted from the LED die 402 from laterally travelling out of the light-emitting structure 400. And with the primary light guiding lens assembly 424, the silicon-based filler 428, and the secondary light guiding lens assembly 426 the light emitted from the LED die 402 may be further guided along a predetermined direction.

It is worth noting that the silicon-based filler 428 may be replaced by another filler with particles capable of scattering, diffusing, and/or reflecting. Therefore, such filler, which may not be silicon-based and thus could be of another compound, could be the transparent filler, the milky type, or the colored filler.

The bonding pads 418 and 422, which are electrically coupled to the metal contacts 408 and 412, may be used as negative and positive electrodes for the LED die 402, respectively. The light-penetrating structure 416 may perform the color converting function especially when the secondary light guiding lens assembly 426 is in the form of a transparent medium. Plus, in another implementation the color converting may not be performed by the light-penetrating structure 416. Rather, the function of the color converting may be realized by the secondary light guiding lens assembly 426. In this particular example, the primary light guiding lens assembly 416 may be in the form of a sapphire transparent material. The heat arising out of the operation of the LED die 402 may be transmitted out of the light-emitting structure 400 through the metal contacts 408 and 412, the substrate 406, and the heat dissipation layer. Additionally, the LED die 402 may be flipped in order to be in contact with the metal contacts 408 and 412 through the bonding pads 418 and 422 using the flip-chip technology. The light-penetrating structure 416 may also function to convert the color of the light emitted from the LED die 402.

The lateral light blocking wall 404 might be omitted and the secondary light guiding lens assembly 426 may immediately connected to the substrate 406. As shown in FIG. 4B, the difference between FIG. 4A and 4B is that the secondary light guiding lens assembly 426 is disposed directly on the substrate 406, and the secondary light guiding lens assembly 426 has a curved shape. The silicon-based filler 428, also shown in FIG. 4A, that may partially or totally fill up the space at least defined by the stacked structure consisting of the LED die 402, the light-penetrating structure 416, and the primary light guiding lens assembly 424, and the secondary light guiding lens assembly 426.

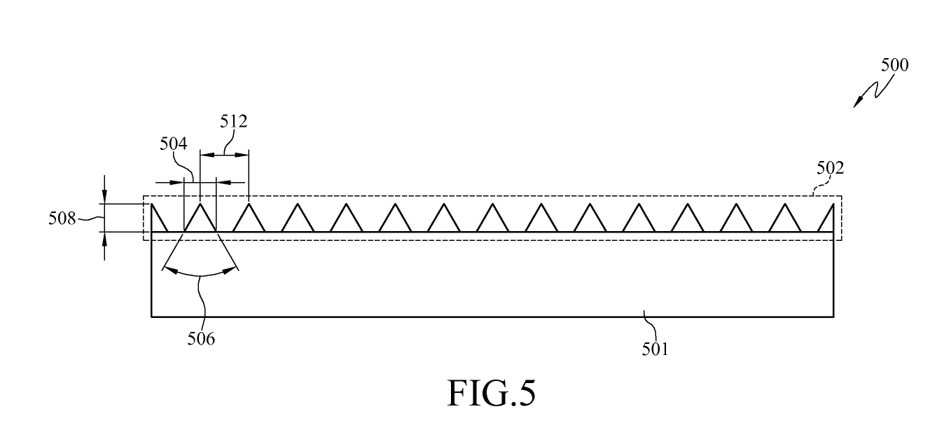

Please refer to FIG. 5 illustrating an example light guiding lens assembly 500 used in the light-emitting structure according to one embodiment of the present disclosure. The light guiding lens assembly 500 may be utilized as the light guiding lens assembly 324, the primary light guiding lens assembly 424, and the secondary light guiding lens assembly 426

The light guiding lens assembly 500 may include a transparent substrate 501 along with a lens array 502 having multiple lens structures placed on the transparent substrate 501. The lens array 502 may be made of acrylic resin, silicone resin and in form of such layer coated on the transparent substrate 501. In one implementation, the transparent substrate 501 may be a polyester PET substrate, sapphire, glass or any substrate to resist temperature and light.

The parameters of the lens array 502 may include the width (pitch) 504, the angle 506, the height 508 of the lens structure, and the distance between the neighboring lens structures. Each lens structure may be different from others in terms of the aforementioned parameters. With the light guiding lens assembly 500, the light emitted from the LED die, may be guided in desired directions.

The foregoing description of the exemplary embodiments of the present disclosure has been presented only for the purposes of illustration and description and is not intended to be exhaustive or to limit the invention to the precise forms disclosed. Many modifications and variations are possible in light of the above teaching.

The embodiments were chosen and described in order to explain the principles of the present disclosure and their practical application so as to activate others skilled in the art to utilize the present disclosure and various embodiments and with various modifications as are suited to the particular use contemplated. Alternative embodiments will become apparent to those skilled in the art to which the present disclosure pertains without departing from its spirit and scope. Accordingly, the scope of the present disclosure is defined by the appended claims rather than the foregoing description and the exemplary embodiments described therein.

What is claimed is:

1. A light-emitting structure, comprising:
a LED die;
a plurality of light-penetrating microspheres, disposed above the LED die, covered a light emitting surface of the LED die; and
a light-penetrating structure, disposed over the LED die and the light-penetrating microspheres, for converting the color of the light.

2. The light-emitting structure according to claim 1, wherein the light-penetrating microspheres are adapted to position in a predetermined fashion in order to cover or surround the entire LED die.

3. The light-emitting structure according to claim 2, wherein the light-penetrating microspheres are directly disposed on the light emitting surface of the LED die.

4. The light-emitting structure according to claim 3, wherein the light-penetrating microspheres are in the form of the plastic powder and cover the LED die by coating.

5. The light-emitting structure according to claim 3, wherein the light-penetrating microspheres cover the LED die through a bonding agent.

6. The light-emitting structure according to claim 3, further comprising:
a lateral light blocking wall, enclosing the LED die and the light-penetrating microspheres, configured to eliminate the possibility of the light emitted from the LED die of laterally travelling out of the light-emitting structure;
wherein the light-penetrating structure is disposed over the LED die and the light-penetrating microspheres and in contact with a top portion of the lateral light blocking wall.

7. The light-emitting structure according to claim 6, further comprising:
a reflective layer, disposed on a top portion of the lateral light blocking wall, for enhancing the reflection of the light emitted from the LED die.

8. The light-emitting structure according to claim 3, further comprising:
a substrate disposed under the LED die;
a plurality of metal contacts connected to the substrate and electrically connected to the LED die;
wherein at least a part of the metal contacts disposed between the substrate and the LED die.

9. The light-emitting structure according to claim 8, further comprising:
a plurality of pads directly connected to the LED die;
wherein each of the pads connected to one of the metal contacts, at least one of the pads is configured to be a negative electrode of the LED die, and at least another one of the pads is configured to be a positive electrode of the LED die.

10. The light-emitting structure according to claim 9, further comprising:
a heat dissipation layer directly connected to the substrate.

11. A light-emitting structure, comprising:
a LED die;
a plurality of light-penetrating microspheres, disposed above the LED die, covered a light emitting surface of the LED die; and
a light-penetrating structure, disposed between the LED die and the light-penetrating microspheres, for converting the color of the light.

12. The light-emitting structure according to claim 11, wherein the light-penetrating microspheres are directly disposed on the light-penetrating structure, and the light-penetrating structure is directly disposed on the substrate.

13. The light-emitting structure according to claim 11, further comprising:
a lateral light blocking wall, enclosing the LED die and the light-penetrating microspheres, configured to eliminate the possibility of the light emitted from the LED die of laterally travelling out of the light-emitting structure.

14. The light-emitting structure according to claim 13, further comprising:
a reflective layer, disposed on a top portion of the lateral light blocking wall, for enhancing the reflection of the light emitted from the LED die.

15. The light-emitting structure according to claim 13, further comprising:
a protective film, disposed over the light-penetrating microspheres and in contact with a top portion of the lateral light blocking wall, for preventing foreign particles and the moisture from invading into the light-emitting structure.

16. The light-emitting structure according to claim 15, further comprising:
a secondary light guiding lens assembly disposed over the light-penetrating microspheres and in contact with a top portion of the lateral light blocking wall.

17. The light-emitting structure according to claim 16, wherein the light-penetrating microspheres are configured to be served as a primary light guiding lens assembly directly disposed on the light-penetrating structure.

18. The light-emitting structure according to claim 17, further comprising:
a silicon-based filler partially or totally fill up the space at least defined by the lateral blocking wall, the secondary light guiding lens assembly, and the stacked structure consisting of the LED die, the light-penetrating structure, and the primary light guiding lens assembly.

19. The light-emitting structure according to claim 11, further comprising:
a substrate disposed under the LED die;
a plurality of metal contacts connected to the substrate and electrically connected to the LED die;
wherein at least a part of the metal contacts disposed between the substrate and the LED die.

20. The light-emitting structure according to claim 19, further comprising:
a plurality of pads directly connected to the LED die;
wherein each of the pads connected to one of the metal contacts, at least one of the pads is configured to be a negative electrode of the LED die, and at least another one of the pads is configured to be a positive electrode of the LED die.
